(19) United States
(12) Patent Application Publication
(10) Pub. No.: US 2016/0087090 A1
(43) Pub. Date: Mar. 24, 2016

(54) RF POWER TRANSISTOR

(71) Applicant: NATIONAL TSING HUA UNIVERSITY, Hsinchu City (TW)

(72) Inventors: Shuo-Hung HSU, Hsinchu City (TW); Chuan-Wei TSOU, Hsinchu City (TW); Yi-Wei LIEN, Hsinchu City (TW)

(73) Assignee: NATIONAL TSING HUA UNIVERSITY, Hsinchu City (TW)

(21) Appl. No.: 14/493,409

(22) Filed: Sep. 23, 2014

(51) Int. Cl. H01L 29/778; H01L 29/423; H01L 29/417; H01L 29/20; H01L 29/205

(52) U.S. Cl. CPC H01L 29/7787; H01L 29/2003; H01L 29/205; H01L 29/41775; H01L 29/42316

(57) ABSTRACT

A radio frequency (RF) power transistor includes: a semiconductor heterostructure that includes an undoped barrier layer and an active layer and that is formed with a continuous two dimensional electron gas (2DEG) channel having an ohmic source-aligned region, an ohmic drain-aligned region and a Schottky-aligned region; agate electrode; and source and drain electrodes. One of the source and drain electrodes includes an ohmic contact and a Schottky contact that extends from the ohmic contact toward the gate electrode. The 2DEG channel is normally on and extends continuously from the ohmic source-aligned region to the ohmic drain-aligned region. The Schottky contact overlaps and is capacitively coupled to the Schottky-aligned region of the 2DEG channel.

### FIELD OF THE INVENTION

This invention relates to a radio frequency (RF) power transistor, and more particularly to an RF power transistor including a hybrid electrode and a continuous two dimensional electron gas (2DEG) channel.

### BACKGROUND OF THE INVENTION

Conventional GaN-based high electron mobility transistors (HEMTs) are known to have a wide bandgap (3.4 eV) and a high electron saturation velocity (2.5×10⁷ cm²/s), and are suitable for high frequency power amplifier applications. FIG. 1 illustrates a conventional HEMT or radio frequency (RF) power transistor that includes a substrate 10, a buffer layer 11 formed on the substrate 10, a GaN active layer 12 formed on the buffer layer 11, an AlGaN barrier layer 13 formed on the active layer 12, source and drain ohmic contacts 14, 15 formed on the barrier layer 13, a gate electrode 16 of a Schottky contact formed on the barrier layer 13, and a protection layer 17 formed on the source and drain electrodes 14, 15, the gate electrode 16 and the barrier layer 13. Conventionally, the source electrode 14 is spaced apart from the drain electrode 15 by a distance (source-to-drain distance, L_{SD}) that is typically around 2 μm. Because of the need for high speed applications of communication systems, many studies have focused on how to enhance high frequency device performance in recent years. Geometric scaling of the gate length has been found to be effective in enhancing device performance, such as cut-off frequency. In addition, conventional HEMTs or RF power transistors exhibit a considerable reduction from DC (direct current) transconductance (operated at zero frequency) to RF transconductance (operated at a high frequency range, ≧1 GHz) due to undesirable material defects such as surface states and traps, which results in undesired DC-to-RF dispersion (i.e., reduction of the transconductance), and deteriorates device performance. Hence, there is a need to suppress the DC-to-RF dispersion.

### SUMMARY OF THE INVENTION

Therefore, an object of the present invention is to provide an RF power transistor that can overcome the aforesaid drawback associated with the prior art.

According to this invention, there is provided an RF power transistor that comprises: a semiconductor heterostructure that includes an undoped barrier layer and an active layer and that is formed with a continuous two dimensional electron gas channel disposed at one side of the active layer which is adjacent to the barrier layer, the electron gas channel having an ohmic source-aligned region, an ohmic drain-aligned region, and a Schottky-aligned region that is disposed between the ohmic source-aligned and drain-aligned regions; a gate electrode that is formed on the semiconductor heterostructure and that is disposed over the barrier layer; and source and drain electrodes formed on the barrier layer. One of the source and drain electrodes includes an ohmic contact and a Schottky contact that extends from the ohmic contact toward the gate electrode along one side of the barrier layer which is distal from the active layer. The other one of the source and drain electrodes includes an ohmic contact. The Schottky contact is disposed between the ohmic contacts of the source and drain electrodes. The ohmic contacts of the source and drain electrodes are aligned with the ohmic source-aligned and drain-aligned regions, respectively. The electron gas channel is normally on and extends continuously from the ohmic source-aligned region to the ohmic drain-aligned region. The Schottky contact overlaps and is capacitively coupled to the Schottky-aligned region of the electron gas channel.

### BRIEF DESCRIPTION OF THE DRAWINGS

In drawings which illustrate embodiments of the invention,

FIG. 1 is a schematic view of a conventional high electron mobility transistor (HEMI);

FIG. 2 is a schematic view of the first embodiment of an RF power transistor according to the present invention;

FIG. 3 is a schematic view of the second embodiment of an RF power transistor according to the present invention;

FIGS. 4A to 4I illustrate consecutive steps of a method of making the second embodiment according to the present invention;

FIG. 5 is a plot of drain current and tranconductance as a function of a gate voltage for Devices A, B, and C;

FIG. 6 is a Smith chart showing measured and modeled parameter S₂₁ of S-parameters for Devices A, B and C; and

FIG. 7 is a plot of current gain as a function of frequency for Devices A, B, and C.

### DETAILED DESCRIPTION OF THE EMBODIMENTS

Before the present invention is described in greater detail with reference to the accompanying embodiments, it should be noted herein that like elements are denoted by the same reference numerals throughout the disclosure.

FIG. 2 illustrates the first embodiment of an RF power transistor according to the present invention.

The RF power transistor is a GaN-based high electron mobility transistor (HEMT), and includes: a substrate 20; a buffer layer 21 formed on the substrate 20; a III-N-type semiconductor heterostructure 22 that is formed on the buffer layer 21, that includes an undoped barrier layer 221 and an active layer 222, and that is formed with a continuous two dimensional electron gas (2DEG) channel 223 disposed at one side of the active layer 222 which is adjacent to the barrier layer 221, the 2DEG channel 223 having an ohmic source-aligned region 223a, an ohmic drain-aligned region 223b, and a first Schottky-aligned region 223c that is disposed between the ohmic source-aligned and drain-aligned regions 223a, 223b; a gate electrode 23 that is formed on the semiconductor heterostructure 22 and that is disposed over the barrier layer 221; source and drain electrodes 24, 25 formed on the barrier layer 221; and a protection layer 26 formed on the source and drain electrodes 24, 25, the gate electrode 23 and the barrier 221. The substrate 20, the buffer layer 21, and the semiconductor heterostructure 22 are stacked one above another along a stacking direction.

The source electrode 24 includes an ohmic contact 241 and a first Schottky contact 242 that extends from the ohmic contact 241 toward the gate electrode 23 along one side of the barrier layer 221 which is distal from the active layer 222. The drain electrode 25 includes an ohmic contact 251. The first Schottky contact 242 is disposed between the ohmic contacts 241, 251 of the source and drain electrodes 24, 25. The ohmic contacts 241, 251 of the source and drain electrodes 24, 25 are aligned with the ohmic source-aligned and drain-aligned regions 223a, 223b of the 2DEG channel 223, respectively, along the stacking direction. The 2DEG channel 223 is normally on, and extends continuously from an end of the ohmic source-aligned region 223a, which is distal from the ohmic drain-aligned region 223b, to an end of the ohmic drain-aligned region 223b, which is distal from the ohmic source-aligned region 223a. The first Schottky contact 242 overlaps the first Schottky-aligned region 223c of the 2DEG channel 223 along the stacking direction, and is capacitively coupled to the first Schottky-aligned region 223c of the 2DEG channel 223.

The ohmic contacts 241, 251 of the source and drain electrodes 24, 25 are spaced apart from each other by a distance (source-to-drain distance, L_{SD}). Preferably, the gate electrode 23 is spaced apart from the first Schottky contact 242 by a distance (source-to-gate distance, L_{GS}) that is less than 0.5 μm, and is further spaced apart from the ohmic contact 251 of the drain electrode 25 by a distance (drain-to-gate distance, L_{GD}) that is less than 0.5 p.m. The first Schottky contact 242 is spaced apart from the ohmic contact 251 of the drain electrode 25 by a distance (effective source-to-drain distance, L_{eff-SD}) that is less than L_{SD} and that is preferably less than 1 p.m.

Preferably, the substrate 20 is made from a material selected from the group consisting of silicon, silicon carbide, sapphire, and GaN.

Preferably, the buffer layer 21 is made from a material, such as AlN and GaN.

Preferably, the active layer 222 is made from a material that has a small bandgap, such as GaN.

Preferably, the barrier layer 221 is made from a material that has a large bandgap, such as AlGaN. The bandgap of the barrier layer 221 is larger than that of the active layer 222. In addition, the barrier layer 221 may be optionally capped by a capping layer (not shown) of GaN, which protects the barrier layer 221 from oxidation.

Preferably, the ohmic contact 241, 251 of each of the source and drain electrodes 24, 25 is a metal stack, such as a four-layer (Ti/Al/Ni/Au or Ti/Al/Ti/Au) metal stack, and is formed using physical vapor deposition techniques, such as e-gun evaporation, followed by annealing under 850° C. In this embodiment, the metal stack of each of the ohmic contacts 241, 251 has a structure of Ti (30 nm)/Al (180 nm)/Ni (40 nm)/Au (50 nm).

Preferably, the first Schottky contact 242 is a metal stack, such as a two-layer (Ni/Au or Pt/Au) metal stack, and is formed using physical vapor deposition techniques. In this embodiment, the metal stack of the first Schottky contact 242 has a structure of Ni (30 nm)/Au (270 nm).

Preferably, the protective layer 26 is made from a material, such as Si₃N₄, Al₂O₃, and AlN.

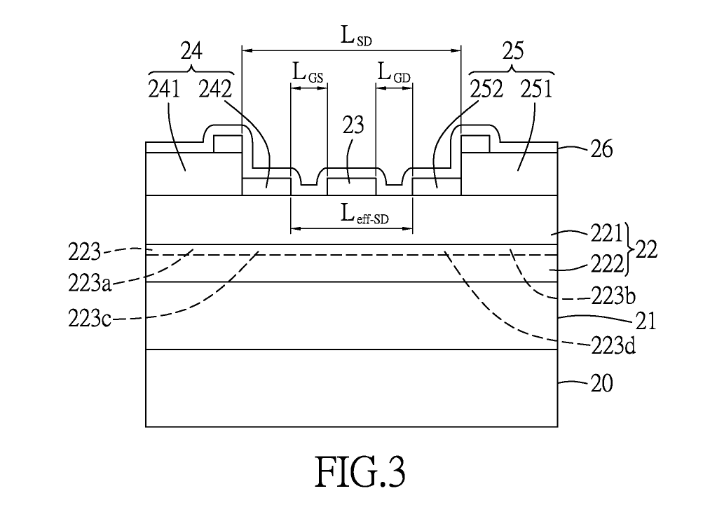

FIG. 3 illustrates the second embodiment of the RF power transistor according to the present invention. The second embodiment differs from the previous embodiment in that the drain electrode 25 further includes a second Schottky contact 252 and the 2DEG channel 223 further has a second Schottky-aligned region 223d. In this embodiment, the second Schottky-aligned region 223d is disposed between the ohmic source-aligned and drain-aligned regions 223a, 223b. The second Schottky contact 252 is disposed between the ohmic contacts 241, 251 of the source and drain electrodes 24, 25, overlaps the second Schottky-aligned region 223d of the 2DEG channel 223 along the stacking direction, and is capacitively coupled to the second Schottky-aligned region 223d of the 2DEG channel 223.

Preferably, the gate electrode 23 is spaced apart from the second Schottky contact 252 by a distance (drain-to-gate distance, L_{GD}) that is less than 0.5 μm.

Preferably, the first Schottky contact 242 is spaced apart from the second Schottky contact 252 by a distance (effective source-to-drain distance, L_{eff-SD}) that is less than 1 μm.

Preferably, the RF power transistor in each of the embodiments has a cut-off frequency greater than 33 GHz.

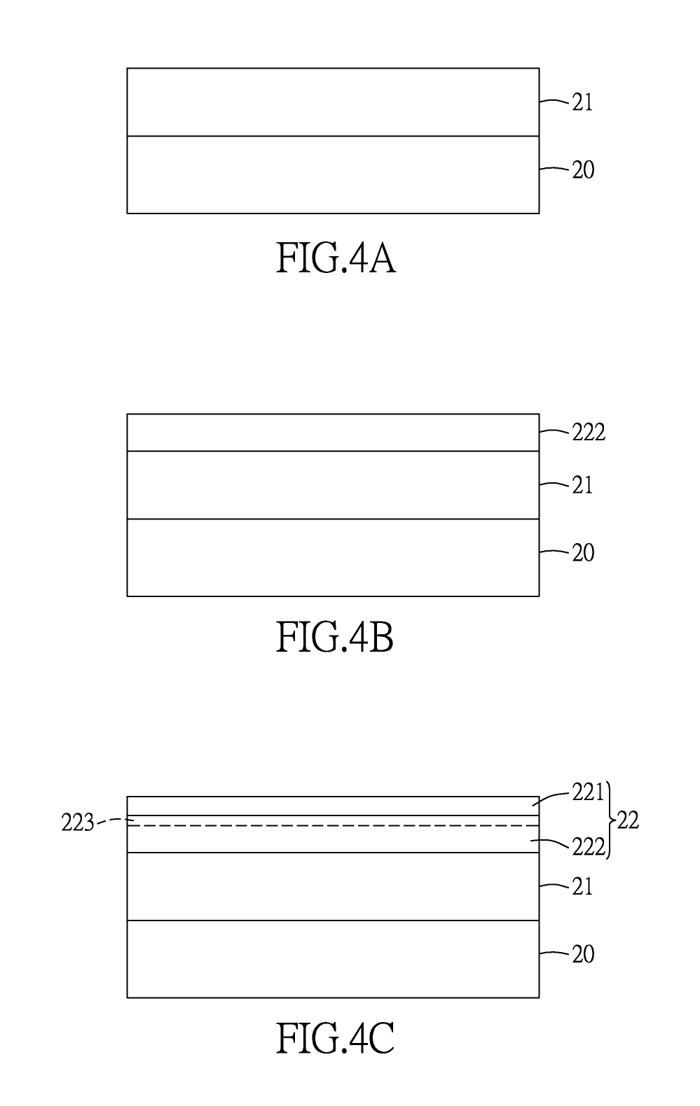

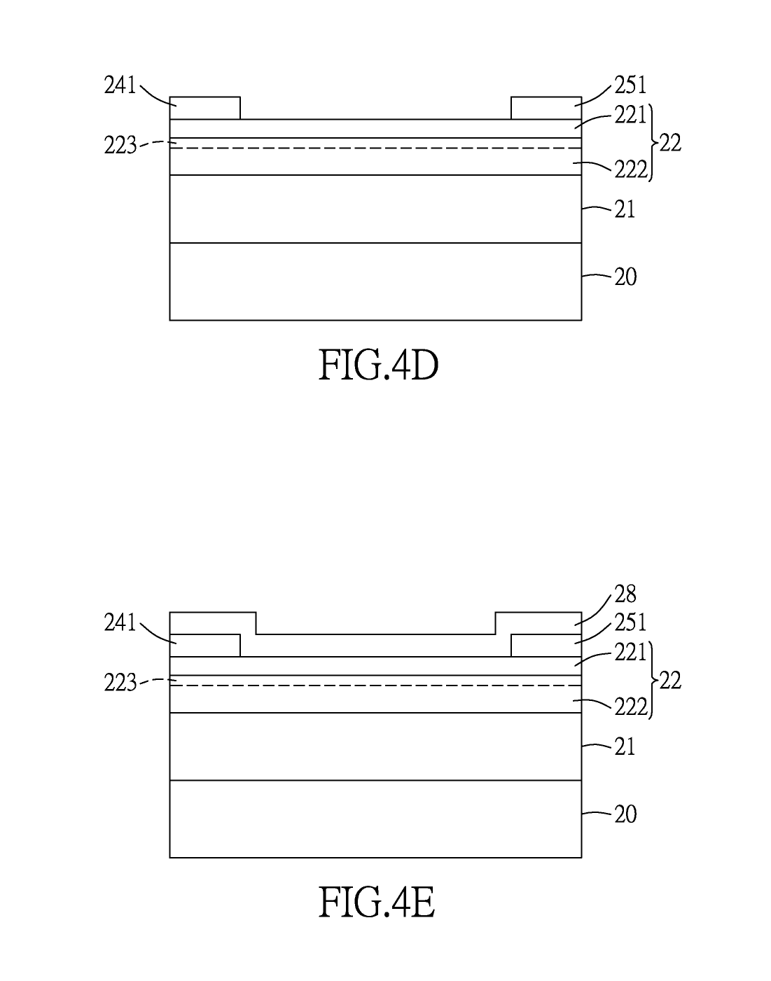

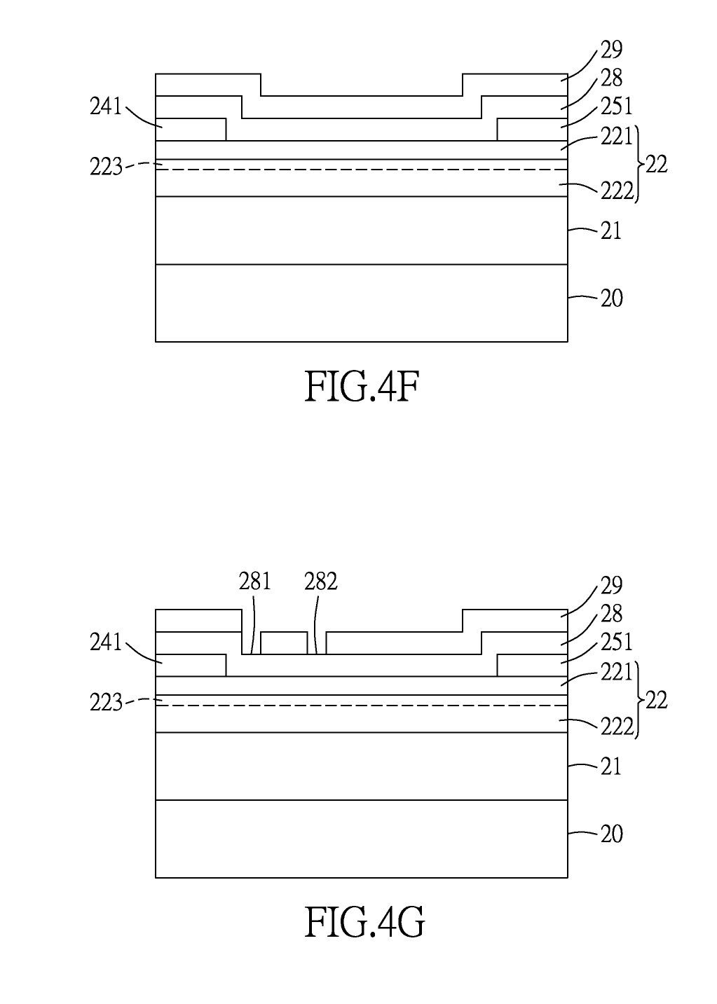

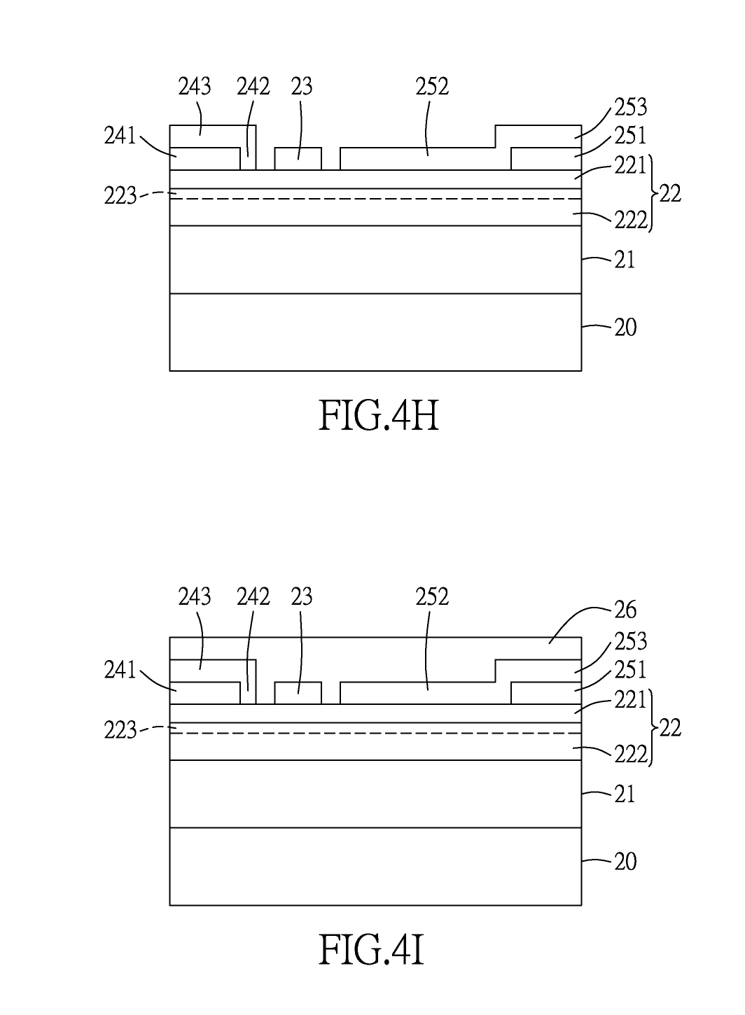

FIGS. 4A to 4I illustrate consecutive steps of a method of making an embodiment of the RF power transistor that has a structure similar to that of the second embodiment. The method includes: forming a buffer layer 21 on a substrate 20 using metal-organic chemical vapor deposition (MOCVD) or molecular beam epitaxy (MBE) technologies (see FIG. 4A); forming an active layer 222 on the buffer layer 21 using MOCVD or MBE technologies (see FIG. 4B); forming a barrier layer 221 on the active layer 222 using MOCVD or MBE technologies (see FIG. 4C), a 2DEG channel 223 being induced in the active layer 222 due to the heterostructure between the barrier layer 221 and the active layer 222; forming source and drain ohmic contacts 241, 251 on the barrier layer 221 using physical vapor deposition (see FIG. 4D), followed by annealing under 850° C.; forming a Schottky-contact layer 28 of a metal stack on the ohmic contacts 241, 251 of the source and drain electrodes 24, 25 and the barrier layer 221 using physical vapor deposition (see FIG. 4E); forming a photoresist layer 29 on the Schottky-contact layer 28 using coating techniques (see FIG. 4F); patterning the photoresist layer 29 to expose etching regions 281, 282 of the Schottky-contact layer 28 (see FIG. 4G); etching the exposed etching regions 281, 282 of the Schottky-contact layer 28 to form the Schottky-contact layer 28 into a gate electrode 23, first and second Schottky contacts 242, 252 and first and second overlapping portions 243, 253 (see FIG. 4H), such that the gate electrode 23 is disposed between and is spaced apart from the first and second Schottky contacts 242, 252, and that the first and second overlapping portions 243, 253 overlap the ohmic contacts 241, 251 of the source and drain electrodes 24, 25, respectively, along a stacking direction; and forming a protection layer 26 on the source and drain electrodes 24, 25 and the barrier layer 221 (see FIG. 4I).

The RF power transistor of the present invention may have a structure that differs from the aforesaid embodiments. For instance, the gate electrode 23 and the first and second Schottky contacts 242, 252 may be formed in different steps with different metallic materials that have different work functions. In addition, a dielectric layer of a dielectric material (not shown), such as Si₃N₄, SiO₂, Al₂O₃, or TiO₂, may be formed on the barrier layer 221 before the formation of the source and drain electrodes 24, 25, so that the gate electrode 23 and the first and second Schottky contacts 242, 252 may be formed on and contact the dielectric layer instead of being formed on and contacting the barrier layer 221 as mentioned in the previously described embodiments.

### <Performance Tests>

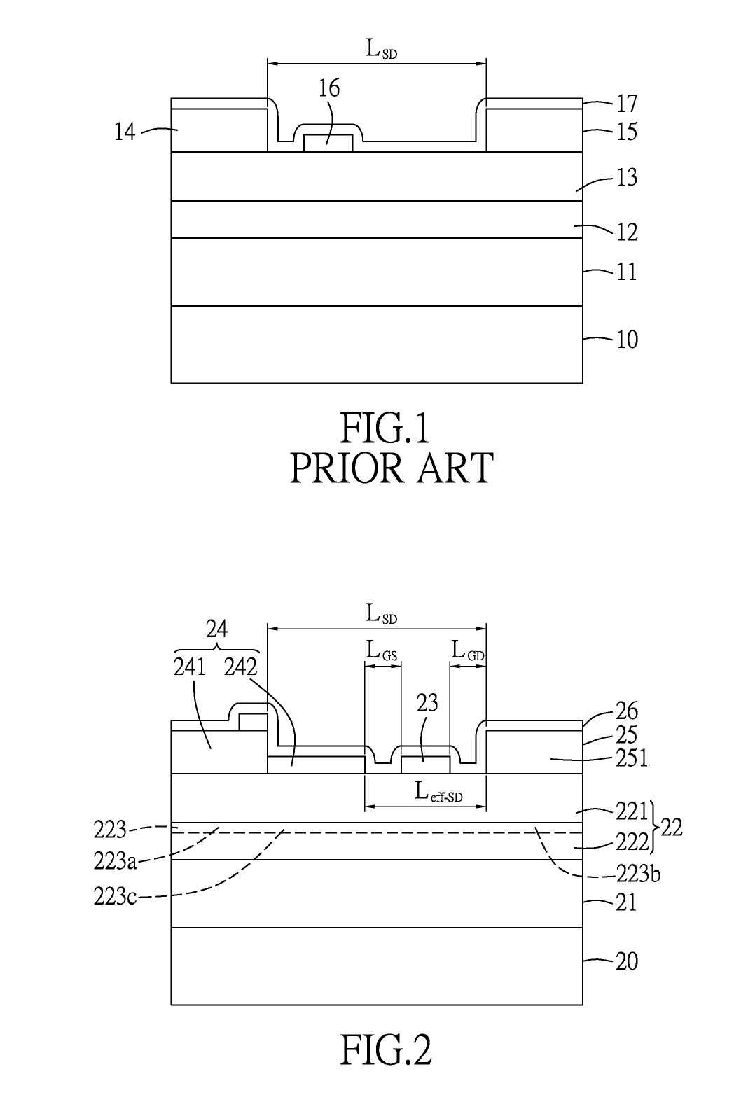

Sample devices of the aforesaid conventional RF power transistor of FIG. 1 (referred herein as Device A), the first embodiment of FIG. 2 (referred herein as Device B), and the second embodiment of FIG. 3 (referred herein as Device C) were prepared for performance tests. All sample devices had a source-to-drain distance (L_{SD}) equal to 2 μm, and a gate length (L_{G}) equal to 0.08 μm. Device A had a source-to-gate distance (L_{GS}) equal to 0.4 μm and a drain-to-gate distance (L_{GD}) equal to 1.52 μm. Both Devices B and C had a source-to-gate distance (L_{GS}) equal to 0.4 μm and a drain-to-gate distance (L_{GD}) equal to 0.4 μm.

FIG. 5 is a plot of the relation of measured drain current (I_{D}) and DC (direct current) transconductance (gₘ=ΔI_{D}/ΔV_{GS}) as a function of a DC bias gate voltage (V_{G} or V_{GS}, varying from −10V to 2V) for Devices A, B and C under a fixed DC bias source-drain voltage (V_{DS}) of 10V. The DC characteristics measurement was conducted using an Agilent B1500A Semiconductor Device Analyzer.

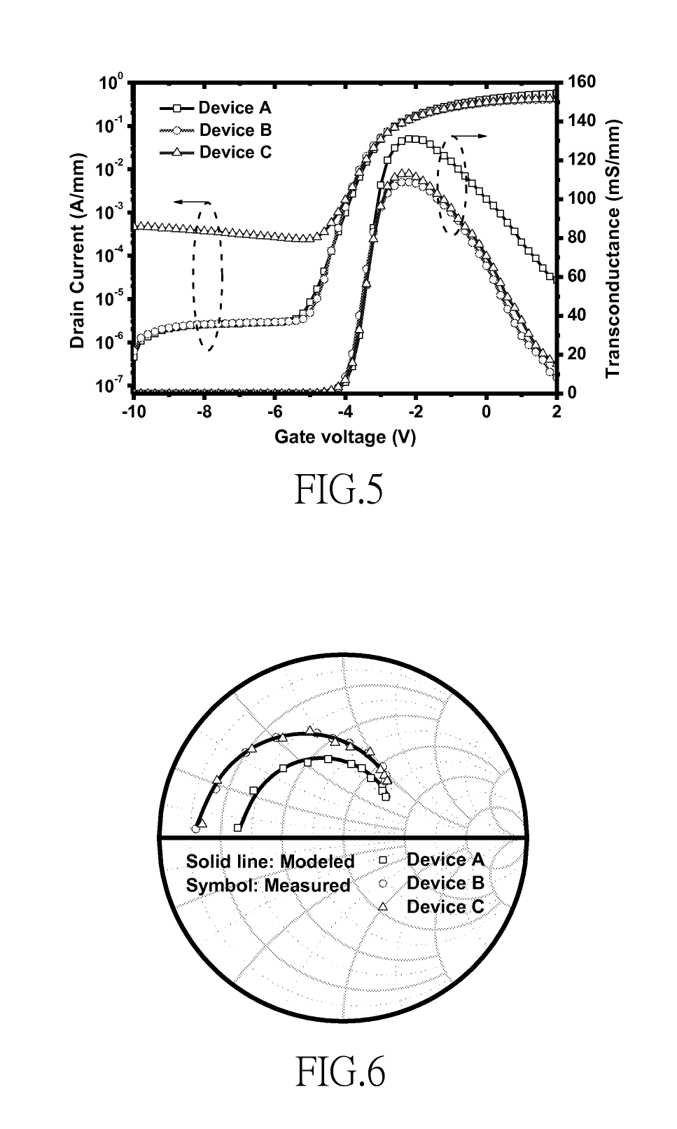

A two-port S-parameter measurement was conducted for obtaining S-parameters (S₁₁, S₂₁, S₂₁ and S₂₂) of Devices A, B and C using an Agilent E8361C PNA Microwave Network Analyzer under a fixed DC bias voltage (V_{GS}=−2.5V, V_{DS}=10V) and a frequency range from 1 GHz to 50 GHz. One of the ports (port 1) is associated with the gate electrode while the other port (port 2) is associated with the drain electrode. FIG. 6 is a Smith chart showing measured and modeled S-parameter S₂₁ (from 1 GHz to 50 GHz) for the three Devices.

A Small-Signal Model (not shown) representing an equivalent circuit including the RF power transistor was established based on the measured S-parameters from 1 GHz to 50 GHz for obtaining the RF transconductances at the high frequency range. Table 1 shows the RF transconductances of the three devices, in which the RF gₘ was extracted from the Small-Signal Model at the fixed DC bias voltage (V_{GS}=−2.5V and V_{DS}=10V).

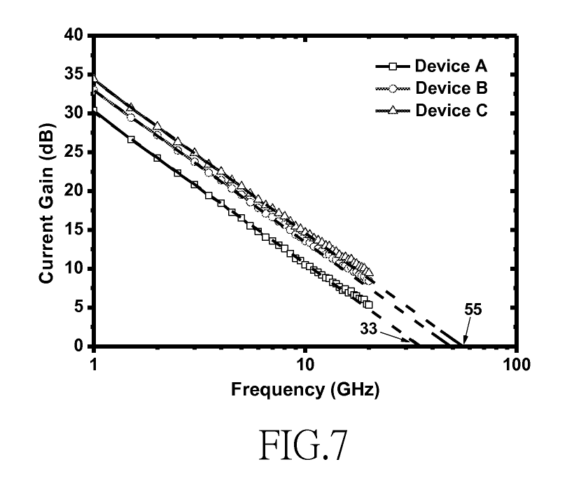

FIG. 7 is a plot of small signal current gain as a function of frequency for Devices A, B and C. The measurement was conducted using an Agilent E8361C PNA Microwave Network Analyzer under a fixed DC bias (V_{GS}=−2.5V and V_{DS}=10V). The small signal current gain (h₂₁) was calculated from measured two-port S-parameter using the following equation

$${h}_{21} = \frac{- 2 {S}_{21}}{( 1 - {S}_{11} ) ( 1 + {S}_{22} ) + {S}_{12} {S}_{21}}$$

where S₁₁, S₂₁, S₂₁ and S₂₂ are S-parameters.

Table 1 summarizes the performance tests for Devices A, B and C.

TABLE 1

| | Schottky | I_{D, max} | DC gₘ | RF gₘ | f_{T} |
|---|---|---|---|---|---|
| Device | extension | (mA/mm) | (mS) | (mS) | (GHz) |
| A | N/A | 568 | 12.6 | 6 | 33 |
| B | Source | 408 | 10.7 | 8.5 | 50 |
| C | Source/Drain | 425 | 11.1 | 8.5 | 55 |

As shown in Table 1, Device A has a DC transconductance (DC gₘ, under V_{GS}=−2.5V) of 12.6 mS and an RF transconductance (RF gₘ, under V_{GS}=−2.5V) of 6.0 mS, which represents a reduction of 52.4% of the transconductance from DC to RF. Device B has a DC transconductance of 10.7 mS (under V_{GS}=−2.5V) and an RF transconductance of 8.5 mS (under V_{GS}=−2.5V), which represents a reduction of 20.6% of the transconductance. Device C has a DC transconductance of 11.1 mS (under V_{GS}=−2.5V) and an RF transconductance of 8.5 mS (under V_{GS}=−2.5V), which represents a reduction of 23.4% of the transconductance. The results show that Devices B and C having hybrid electrode(s) can effectively suppress the DC-to-RF dispersion and exhibit a higher RF transconductance under high frequency operation as compared to Device A.

The cut-off frequency (f₁) (at the current gain=1 or 0 dB) of each device can be determined or extracted from FIG. 7. The results show that the cut-off frequencies (f₁) of Device B and C are much higher than that of Device A. Particularly, Device C has a cut-off frequency of 55 GHz which is 1.67 times of that of Device A. Hence, the inclusion of the first Schottky contact 242 in the source electrode 24 and/or the second Schottky contact 252 in the drain electrode 25 of the RF power transistor, which reduces the source-to-gate distance (L_{GS}) and/or the drain-to-gate distance (L_{GD}), may alleviate DC-to-RF dispersion and enhance the cut-off frequency of the RF power transistor for improving high frequency performance.

While the present invention has been described in connection with what are considered the most practical embodiments, it is understood that this invention is not limited to the disclosed embodiments but is intended to cover various arrangements included within the spirit and scope of the broadest interpretation and equivalent arrangements.

1. A radio frequency (RF) power transistor comprising:
a semiconductor heterostructure that includes an undoped barrier layer and an active layer and that is formed with a continuous two dimensional electron gas channel disposed at one side of said active layer which is adjacent to said barrier layer, said electron gas channel having an ohmic source-aligned region, an ohmic drain-aligned region, and a first Schottky-aligned region that is disposed between said ohmic source-aligned region and said ohmic drain-aligned region; a gate electrode that is formed on said semiconductor heterostructure and that is disposed over said barrier layer; and
source and drain electrodes formed on said barrier layer, one of said source and drain electrodes including an ohmic contact and a first Schottky contact that extends from said ohmic contact toward said gate electrode along one side of said barrier layer which is distal from said active layer, the other one of said source and drain electrodes including an ohmic contact, said first Schottky contact being disposed between said ohmic contacts of said source and drain electrodes, said ohmic contacts of said source and drain electrodes being aligned with said ohmic source-aligned and drain-aligned regions, respectively;
wherein said electron gas channel is normally on and extends continuously from said ohmic source-aligned region to said ohmic drain-aligned region;
wherein said first Schottky contact overlaps and is capacitively coupled to said first Schottky-aligned region of said electron gas channel; and
wherein said gate electrode is spaced apart from said first Schottky contact of said one of said source and drain electrodes by a distance that is less than 0.5 μm, and is spaced apart from said ohmic contact of said other one of said source and drain electrodes by a distance that is less than 0.5 μm.

2. The RF power transistor of claim 1, wherein said other one of said source and drain electrodes further includes a second Schottky contact, said electron gas channel further having a second Schottky-aligned region that is disposed between said ohmic source-aligned and drain-aligned regions, said second Schottky contact being disposed between said ohmic contacts of said source and drain electrodes and overlapping and being capacitively coupled to said second Schottky-aligned region of said electron gas channel.

3. (canceled)

4. The RF power transistor of claim 2, wherein said gate electrode is spaced apart from said second Schottky contact by a distance that is less than 0.5 μm.

5. The RF power transistor of claim 4, wherein said first Schottky contact is spaced apart from said second Schottky contact by a distance that is less than 1 μm.

6. The RF power transistor of claim 1, wherein said barrier layer is made from AlGaN.

7. The RF power transistor of claim 1, wherein said active layer is made from GaN.

8. The RF power transistor of claim 1, wherein said RF power transistor has a cut-off frequency greater than 33 GHz.

9. The RF power transistor of claim 1, wherein said gate electrode is spaced apart from said first Schottky contact of said one of said source and drain electrodes by a distance of 0.4 μm, and is spaced apart from said ohmic contact of said other one of said source and drain electrodes by a distance of 0.4 μm.
